(19) United States
(12) Patent Application Publication
(10) Pub. No.: US 2025/0353509 A1
(43) Pub. Date: Nov. 20, 2025

(54) Onboard Control Unit

(71) Applicant: Hitachi Astemo, Ltd., Hitachinaka-shi, Ibaraki (JP)

(72) Inventors: Kenji KOGO, Chiyoda-ku, Tokyo (JP); Takayasu NORIMATSU, Chiyoda-ku, Tokyo (JP); Masaru KOKUBO, Chiyoda-ku, Tokyo (JP); Koji MAEDA, Hitachinaka-shi, Ibaraki (JP)

(21) Appl. No.: 18/863,704

(22) PCT Filed: May 18, 2023
(86) PCT No.: PCT/JP2023/018602

§ 371 Date: Jul. 30, 2025

(30) Foreign Application Priority Data
May 27, 2022 (JP) 2022-087113

(51) Int. Cl. B60W 50/02; G01R 31/00

(52) U.S. Cl. CPC B60W 50/0205; G01R 31/007; B60W 2050/021; B60W 2556/20

(57) ABSTRACT

Provided is an onboard control unit that can quickly detect abnormalities in an onboard device such as an actuator or a sensor including a detection unit, and can be used to construct a robust onboard network system. The onboard control unit comprises: onboard devices in charge of controlling vehicle travel, such as a sensor and an actuator; and an electronic control unit that collects information on the onboard devices, wherein an abnormality of an onboard device becomes apparent in a driving power supply of the onboard device. Accordingly, power to be supplied to the electronic control unit is supplied as driving power to the onboard device, a value of current flowing through a power-feeding path thereof is measured by using an ammeter, the state of the onboard device is monitored on the basis of the current value, and whether an abnormality has occurred in the onboard device is determined by a control unit.

### TECHNICAL FIELD

The present invention relates to an onboard control unit.

### BACKGROUND ART

In recent years, there have been social challenges such as reduction of the number of traffic accidents, reduction of traffic accident damage, and provision of transportation means and the like to vulnerable road users, and technological development for realizing automated driving of vehicles has been advanced. Exemplary functions required for each level of automated driving are defined by SAE (Society of Automotive Engineers). As for the responsibility of the accident that has occurred, SAE defines that the driver is responsible for the accident in the case of a vehicle of automated driving level 2 or a lower level, and the system is responsible for the accident in the case of a vehicle of automated driving level 3 or a higher level. Automated driving level 3 is conditional automated driving.

In the case of automated driving level 3, the system performs driving control and surrounding monitoring during normal driving, and the driver performs driving control only in an emergency. In this automated driving level 3, the driver does not always hold the steering wheel, and thus the driving control of the vehicle cannot be immediately transferred to the driver. Thus, it is required to travel safely on the system side in a time zone until the system detects a failure and shifts the driving control of the vehicle to the driver. That is, it is necessary to construct a redundant system that does not completely stop even at the time of failure but transitions to a degeneration system to travel while limiting functions or the like.

As described above, with the improvement of the automated driving level, safe running is required under the control of the system. Thus, the number of sensors such as cameras and radars for surrounding monitoring increases. As the number of sensors increases, the number of wire harnesses to which the sensors are connected increases. In addition, existing devices directly related to vehicle traveling, such as a brake and a steering, also require a dual system, and it is necessary to connect a larger number of cables than before. This greatly increases the number of wire harnesses.

Thus, in the onboard network, a zone architecture has been proposed in which high-speed Ethernet is introduced and hierarchized from the network for each domain. The zone architecture includes an integrated electronic control unit (ECU) that performs traveling control of the vehicle and a zone ECU that aggregates information of sensors and actuators for each location of the vehicle regardless of the domain. Each sensor or actuator is configured to communicate with the integrated ECU via the zone ECU. Thus, a large amount of data communication with a low delay is required between the integrated ECU and the zone ECU called the backbone network, and high-speed communication of 100 Mbps or more is required. In the future, camera transmission with image quality of 4 K or 8 K is also assumed, and introduction of high-speed communication of 10 Gbps is also considered. This zone architecture configuration is expected to significantly reduce cables.

Meanwhile, to efficiently transmit information with a simple configuration in the onboard network, an onboard communication device having a path for transmitting a low-frequency signal separately from a high-frequency portion of communication has been proposed (see, for example, Patent Literature 1). Patent Literature 1 discloses that “provided are a high-band communication unit that generates a high-band signal including communication information and outputs the high-band signal to a differential signal line, and a low-band communication unit that generates a DC signal or a low-band signal and outputs the DC signal or the low-band signal to the differential signal line”.

### CITATION LIST

### Patent Literature

Patent Literature 1: JP 2018-196084 A

### SUMMARY OF INVENTION

### Technical Problem

In the conventional technology described in Patent Literature 1, reception signal quality of only the high-band communication unit is monitored by providing a path for transmitting a low-frequency signal separately from a high-frequency portion of communication. However, for a low-frequency portion which includes power transmission and power supply/reception, only a significant change such as opening or short circuit is checked, and a detailed numerical value is not examined. Usually, a sensor mounted on a vehicle includes a detection unit that performs detection and control, and a communication unit that performs data communication with the outside. When an abnormality has occurred in the communication unit, the abnormality can be found by monitoring the high-frequency communication unit as in the conventional technology described in Patent Literature 1. However, when the communication unit is normal, but an abnormality has occurred in the detection unit, the communication operates normally, and thus the abnormality that has occurred in the detection unit cannot be detected only through the high frequency. To construct a robust onboard network system, it is required to quickly detect an abnormality of an onboard device such as a sensor or an actuator including a detection unit.

The present invention has been made in view of the above-described circumstance, and an object thereof is to provide an onboard control unit capable of quickly detecting an abnormality of an onboard device such as a sensor or an actuator including a detection unit and constructing a robust onboard network system.

### Solution to Problem

To solve the above problem, for example, the configuration described in the claims is adopted.

The present application includes a plurality of solutions to the problem, and examples of the solutions include an onboard control unit including an onboard device that controls traveling of a vehicle, an electronic control unit that collects information of the onboard device, and a power supply wire that feeds power supplied to the electronic control unit to the onboard device, wherein the electronic control unit includes a current measurement unit that measures a value of a current flowing through the power supply wire and a control unit that determines whether an abnormality has occurred in the onboard device based on the current value measured by the current measurement unit.

### Advantageous Effects of Invention

The present invention can quickly detect an abnormality of an onboard device such as a sensor or an actuator connected to an electronic control unit with a simple structure. Thus, it is possible to construct a robust onboard network system.

Problems, configurations, and effects other than those described above will be clarified by the following description of embodiments.

### BRIEF DESCRIPTION OF DRAWINGS

FIG. 1 is a configuration diagram conceptually illustrating a configuration example of an onboard control unit according to Example 1 of the present invention.

FIG. 2 is a configuration diagram conceptually illustrating a configuration example of an onboard control unit according to Example 2 of the present invention.

FIG. 3 is a waveform diagram illustrating a voltage waveform of a data wire and a voltage waveform of power to be superimposed on data in the onboard control unit according to Example 2 of the present invention.

FIG. 4 is a block diagram illustrating a configuration example of a filter circuit in the onboard control unit according to Example 2 of the present invention.

FIG. 5 is a connection diagram of an onboard network architecture to which Example 3 of the present invention is applied.

FIG. 6 is a configuration diagram conceptually illustrating a configuration example of an onboard control unit according to Example 3 of the present invention.

FIG. 7 is a characteristic diagram of consumption current-credibility of data in the onboard control unit according to Example 3 of the present invention.

FIG. 8 is a schematic diagram of data filtering through area electronic control for selecting data of the onboard device in accordance with a vehicle control cycle in the onboard control unit according to Example 3 of the present invention.

FIG. 9 is a configuration diagram conceptually illustrating a configuration example of an onboard control unit according to Example 4 of the present invention.

FIG. 10 is a characteristic diagram of consumption current-credibility of data in a case where temperature information of the onboard device is used as a determination parameter of credibility of data in the onboard control unit according to Example 4 of the present invention.

FIG. 11 is a connection diagram of an onboard network architecture according to Example 5 of the present invention.

FIG. 12 is a configuration diagram conceptually illustrating a configuration example of an onboard control unit according to Example 5 of the present invention.

FIG. 13 is a circuit diagram illustrating a configuration example of a power supply redundancy circuit in the onboard control unit according to Example 5 of the present invention.

### DESCRIPTION OF EMBODIMENTS

Hereinafter, modes for carrying out the present invention (hereinafter, referred to as embodiments) and specific examples thereof will be described.

In an embodiment of the present invention, in an onboard control unit including an onboard device that controls vehicle traveling and an electronic control unit that collects information of the onboard device, power supplied to the electronic control unit is supplied to the onboard device as its driving power. Examples of the onboard device that controls the traveling of the vehicle include sensors such as a CMOS sensor (camera), a radar, an acceleration sensor, and a GPS sensor, and an actuator that performs a physical operation of the vehicle.

In the present embodiment, in the onboard control unit having the above configuration, the abnormality of the onboard device such as a sensor or an actuator appears in the power supplied from the electronic control unit to the onboard device. Specifically, it appears as a change in the current value. Thus, the power consumption of the onboard device such as a sensor or an actuator is monitored by measuring the value of the current flowing through the power-feeding path for supplying power to the onboard device with a current measurement unit. Then, a control unit determines whether an abnormality has occurred in the onboard device such as a sensor or an actuator based on the current value measured by the current measurement unit.

This enables monitoring of the power supplied to the onboard device through the power-feeding path in addition to the communication data of the onboard device such as a sensor and an actuator in the same electronic control unit, and it is possible to check the state of the onboard device as the connection destination from the electronic control unit. In general, the onboard device such as a sensor or an actuator also has a self-diagnosis function and has a function of notifying an alert. However, according to the present invention, even when an alert cannot be transmitted when the communication unit of the onboard device has an abnormality, the abnormality of the onboard device can be detected in the electronic control unit as the connection destination, and the abnormality can be promptly notified to a higher-level device. Thus, a robust onboard network system can be constructed.

Hereinafter, specific examples of the present embodiment will be described with reference to the accompanying drawings. In the present specification and the drawings, components having substantially the same function or configuration are denoted by the same reference numerals, and overlapping description is omitted.

### Example 1

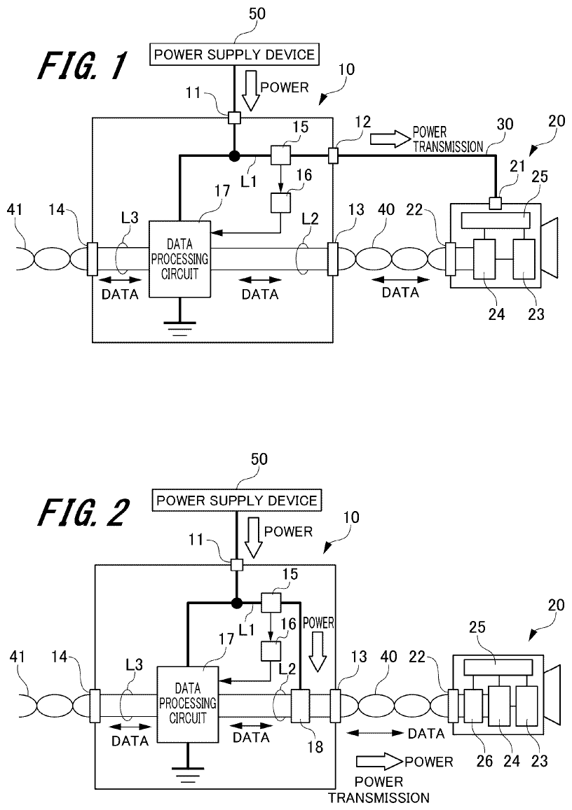

Example 1 of the present invention is an example of a system configuration in which an electronic control unit (ECU) 10 and an onboard device 20 are connected via a power supply wire 30 and a data wire 40. FIG. 1 is a configuration diagram conceptually illustrating a configuration example of an onboard control unit according to Example 1 of the present invention.

Examples of the onboard device 20 that controls vehicle traveling include a sensor and an actuator. Here, a case of a sensor such as a CMOS sensor, a radar, an acceleration sensor, or a GPS sensor will be described as an example. The same applies to the examples described later in terms of exemplifying a sensor as the onboard device 20.

The electronic control unit 10 includes at least power supply terminals 11 and 12 and data input/output terminals 13 and 14 as input/output interfaces with the outside. The power supply terminal 11 is supplied with power from an external power supply device 50 such as a battery cell or a battery.

The onboard device 20 includes at least the power supply terminal 21 and the data input/output terminal 22 as an input/output interface with the outside. The power supply wire 30 is connected between the power supply terminal 12 of the electronic control unit 10 and the power supply terminal 21 of the onboard device 20. The data wire 40 is connected between the data input/output terminal 13 of the electronic control unit 10 and the data input/output terminal 22 of the onboard device 20.

The power supplied from the external power supply device 50 to the electronic control unit 10 is supplied to a data processing circuit 17 described later in the electronic control unit 10, and is supplied to the power supply terminal 21 of the onboard device 20 through a power-feeding path including the power supply terminal 21 and the power supply wire 30 as the power for driving the onboard device 20. Data is exchanged between the electronic control unit 10 and the onboard device 20 through the data wire 40, and the electronic control unit 10 collects information (in the present example, sensor information) of the onboard device 20 through the data wire 40.

The electronic control unit 10 includes at least an ammeter 15, which is an example of a current measurement unit, a control unit 16, and a data processing circuit 17 therein. The ammeter 15 is disposed in a power-feeding path L1 between the power supply terminal 11 and the power supply terminal 12, and it monitors the power for driving the onboard device 20 by measuring the value of the current flowing through the power supply wire 30 for supplying power to the onboard device 20. Here, the abnormality of the onboard device 20 appears in the power supplied to the onboard device 20 as a change in the value of the current flowing through the power supply wire 30. Thus, measuring the value of the current flowing through the power supply wire 30 and monitoring the power consumption of the onboard device 20 makes it possible to grasp whether an abnormality has occurred in the onboard device 20.

The control unit 16 includes, for example, a microcomputer, and it determines whether an abnormality has occurred in the onboard device 20 based on the current value measured by the ammeter 15. As an example, when the current value measured by the ammeter 15, that is, the value of the current flowing through the power supply wire 30 becomes equal to or larger than a predetermined current value, the control unit 16 detects that the power consumption of the onboard device 20 has increased and an abnormality has occurred in the onboard device 20, and passes a detection signal indicating the abnormality to the data processing circuit 17.

The data processing circuit 17 is a circuit for processing signals, such as a switch, an LSI, or a system on chip (SoC), is connected to the data input/output terminal 13 by an impedance-designed line L2, and exchanges data with the onboard device 20 through the line L2 and the data wire 40. Like a watchdog timer, the data processing circuit 17 has a function of confirming reception of frames at regular intervals and confirming normalization of a communication unit 24 described later of the onboard device 20. A detection signal indicating that an abnormality has occurred in the onboard device 20 is provided from the control unit 16 to the data processing circuit 17.

The data processing circuit 17 is connected to the data input/output terminal 14 via an impedance-designed line L3. The data input/output terminal 14 is connected with a data wire 41.

The data processing circuit 17 supplies the data exchanged with the onboard device 20 and the detection signal indicating that an abnormality has occurred in the onboard device 20 acquired from the control unit 16 to a higher-level device of the electronic control unit 10 through the data input/output terminal 14 and the data wire 41.

The onboard device 20 is provided therein with at least a detection unit 23 that senses the surroundings, such as a CMOS sensor, a radar, an acceleration sensor, or a GPS sensor, and a communication unit 24 that periodically transmits and receives data to and from the electronic control unit 10 and exchanges data with the electronic control unit 10. In addition, the onboard device 20 is provided with a power supply stabilization circuit 25 to stabilize the power supplied through the power supply terminal 21. The power supply stabilization circuit 25 includes a capacitor and a Schottky barrier diode, and it supplies stabilized power to the detection unit 23 and the communication unit 24.

As described above, the onboard control unit according to Example 1 has a system configuration in which the electronic control unit 10 and the onboard device 20 are connected via the power supply wire 30 and the data wire 40, that is, a system configuration in which the data communication destination of the onboard device 20 and the power supply source of the onboard device 20 are the same electronic control unit 10.

In the onboard control unit according to Example 1 of the system configuration, the electronic control unit 10 monitors the frequency of communication and the number of error frames received from the onboard device 20 through the data wire 40 to monitor the state of the communication unit 24 of the onboard device 20. Further, the value of the current flowing through the power supply wire 30 is measured by the ammeter 15, the consumption current of the onboard device 20 is monitored, and thus the state of the detection unit 23 is also managed.

In this manner, according to the onboard control unit according to Example 1, even when an abnormality has occurred in the communication unit 24 of the onboard device 20 and an alert cannot be transmitted from the communication unit 24, the electronic control unit 10 to which the onboard device 20 is connected can detect an abnormality when the abnormality has occurred in the onboard device 20 from the measurement result of the value of the current flowing through the power-feeding path L1 measured by the ammeter 15.

As a result, it is possible to quickly grasp that an abnormality has occurred in the onboard device 20 and notify the higher-level device of the abnormality, and thus a robust onboard network system can be constructed.

### Example 2

Example 2 of the present invention is an example of a system configuration in which the number of cables is reduced by applying a power supply superposition technology of superimposing a power supply on data. As the power supply superposition technology, for example, a known power over data lines (PoDL) technology can be used. FIG. 2 is a configuration diagram conceptually illustrating a configuration example of an onboard control unit according to Example 2 of the present invention.

To apply the power supply superimposition technology in the onboard control unit according to Example 2, the electronic control unit 10 includes a filter circuit 18 as an example of a superimposition circuit. The filter circuit 18 is disposed in the line L2 connecting the data processing circuit 17 and the data input/output terminal 13, and it superimposes the power passing through the ammeter 15 on the data transmitted from the data processing circuit 17 to the onboard device 20 through the line L2, the data input/output terminal 13, and the data wire 40. The data wire 40 has a function of the power supply wire 30 in the onboard control unit according to Example 1 illustrated in FIG. 1, and it transmits data on which the power is superimposed to the onboard device 20. That is, the data wire 40 also serves as the power supply wire 30 in the onboard control unit according to Example 1, and it transmits power and data (that is, data on which power is superimposed) to the onboard device 20 using one cable.

In this manner, in the onboard control unit according to Example 2, the filter circuit 18 provided in the electronic control unit 10 multiplexes data and power to superimpose the power on the data. Also in the onboard device 20, a filter circuit 26 is disposed at a subsequent stage of the data input/output terminal 22, that is, on the data input side, and demultiplexing of data and power is performed in the filter circuit 26. The power demultiplexed in the filter circuit 26 is supplied to and stabilized in the power supply stabilization circuit 25, and then supplied to the detection unit 23 and the communication unit 24. The data demultiplexed in the filter circuit 26 is supplied to the communication unit 24.

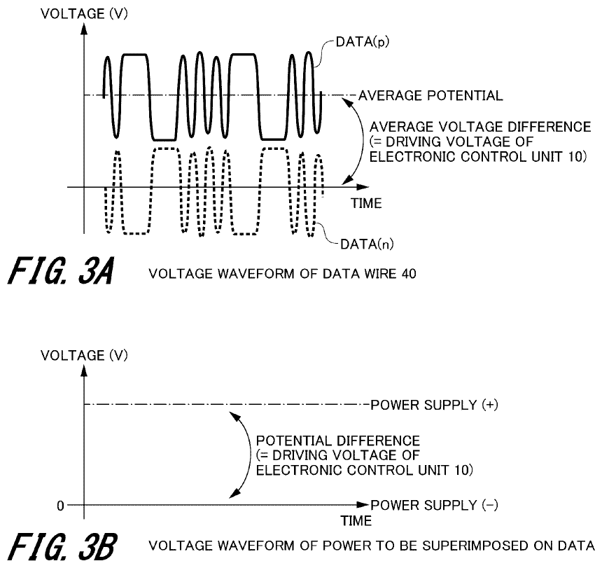

FIG. 3 illustrates voltage waveform A of data wire 40 that transmits the data on which power is superimposed, and voltage waveform B of the power to be superimposed on data. The average voltage difference between the power supply (+) and the power supply (−) is the drive voltage of the electronic control unit 10.

As the data wire 40 for transmitting the data on which power is superimposed, a high-frequency cable such as an impedance-designed coaxial or differential pair can be used. Basically, the high-frequency cable is physically formed of two wires, and a power supply (+) and a power supply (−) are superimposed on each of the two wires. In particular, in the onboard network system, to reduce the number of cables, bidirectional data communication is performed by one pair of cables such as an unshielded twist pair (UTP), a shielded twist pair (STP), and a shielded parallel pair (SPP). In addition to the data of DATA (p) and DATA (n), an average voltage difference between the two pieces of data forms a waveform serving as a drive voltage of the electronic control unit 10.

### [Filter Circuit]

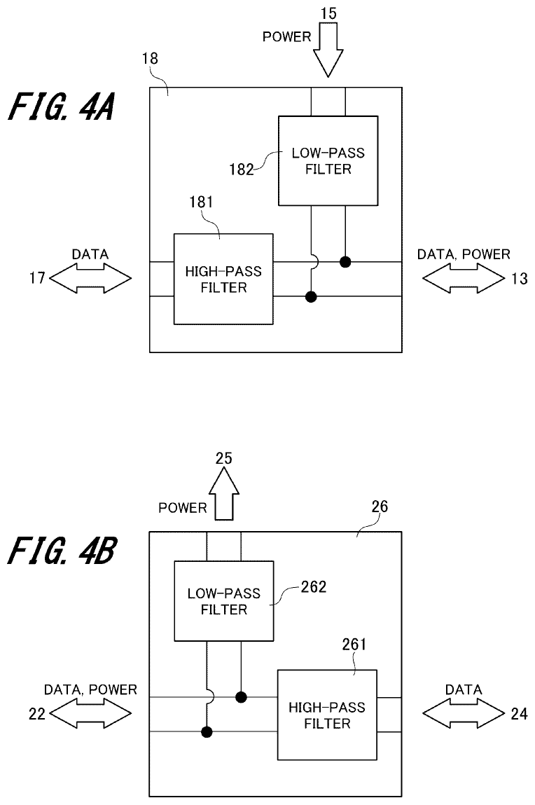

FIG. 4 is a block diagram illustrating a configuration example of a filter circuit in the onboard control unit according to Example 2. FIG. 4A illustrates a configuration example of the filter circuit 18 on the electronic control unit 10 side, and FIG. 4B illustrates a configuration example of the filter circuit 26 on the onboard device 20 side. The data and the power have different frequency components. Thus, the filter circuit 18 on the electronic control unit 10 side performs combining with filters having different frequency characteristics, and the filter circuit 26 on the onboard device 20 side performs demultiplexing with filters having different frequency characteristics.

The filter circuit 18 on the electronic control unit 10 side has a circuit configuration including two filters of a high-pass filter 181 and a low-pass filter 182 having different frequency characteristics.

The high-pass filter 181 is provided between the data processing circuit 17 and the data input/output terminal 13. The high-pass filter 181 is realized by a capacitor or the like disposed in series. With this configuration, the high-pass filter 181 can transmit only data in a high-frequency band without transmitting a signal in a low-frequency band such as power.

The low-pass filter 182 is provided between the ammeter 15 and the data input/output terminal 13. The low-pass filter 182 is realized by disposing coils and ferrite beads in series. With this configuration, the low-pass filter 182 can transmit a signal in a low-frequency band such as power without transmitting data in a high-frequency band, and it superimposes the power supplied via the ammeter 15 on the data that has passed through the high-pass filter 181.

Using the filter circuit 18 having the above configuration allows the electronic control unit 10 to combine data and power. That is, the electronic control unit 10 combines the data that has passed through the high-pass filter 181 and the power that has passed through the low-pass filter 182, and supplies the combined power superimposed data to the onboard device 20 through the data wire 40.

The filter circuit 26 on the onboard device 20 side has a circuit configuration including two filters of a high-pass filter 261 and a low-pass filter 262 having different frequency characteristics.

The high-pass filter 261 is provided between the data input/output terminal 22 and the communication unit 24. The high-pass filter 261 is realized by a capacitor or the like disposed in series. With this configuration, the high-pass filter 261 can transmit only data in a high-frequency band without transmitting a signal in a low-frequency band such as power. That is, the high-pass filter 261 transmits only data among the data on which power input through the data input/output terminal 22 is superimposed, and supplies the data to the communication unit 24.

The low-pass filter 262 is provided between the data input/output terminal 22 and the power supply stabilization circuit 25. The low-pass filter 262 is realized by disposing a coil or ferrite beads in series. With this configuration, the low-pass filter 262 can transmit a signal in a low-frequency band such as power without transmitting data in a high-frequency band, and it demultiplexes the power by transmitting only the power among the data on which the power input through the data input/output terminal 22 is superimposed. The demultiplexed power is supplied to and stabilized in the power supply stabilization circuit 25, and then supplied to the detection unit 23 and the communication unit 24.

In this manner, the onboard control unit of according to Example 2, in which the power supply superposition technology of superimposing the power supply (power) on data is applied, and the power transmission and the data communication are performed by the same cable (data wire 40), can reduce the number of cables. With the reduction in the number of cables, the power supply terminal 12 of the electronic control unit 10 and the power supply terminal 21 of the onboard device 20 in the onboard control unit according to Example 1 illustrated in FIG. 1 become unnecessary, which can simplify the system configuration.

### Example 3

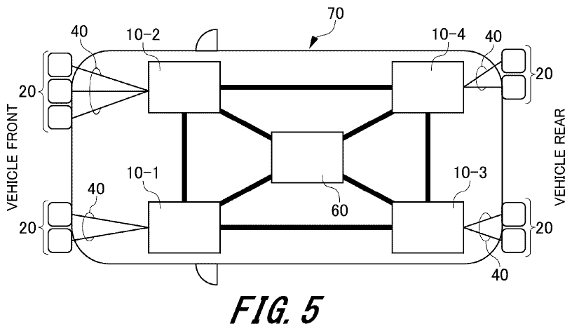

Example 3 of the present invention is an example of a zone architecture configuration that includes an integrated electronic control unit (integrated ECU) as a higher-level device of the electronic control unit 10 and integrates control processing in the integrated electronic control unit. FIG. 5 is a connection diagram of an onboard network architecture to which Example 3 of the present invention is applied. The onboard network system includes three types of components: an integrated electronic control unit (integrated ECU) 60, an electronic control unit (zone ECU) 10, and the onboard device 20. Here, for example, a system configuration including four electronic control units 10-1 to 10-4 is illustrated, but the number of electronic control units 10 is not limited to four.

The onboard device 20 is a device such as a sensor or an actuator, is disposed in every corner of the vehicle 70 as illustrated in FIG. 5, and executes surroundings monitoring, engine information acquisition, control, and the like. As the onboard device 20, there are various types of devices.

The integrated electronic control unit 60 grasps the entire vehicle 70 and the surrounding situation of the vehicle 70 based on various information given from each of the onboard devices 20 via the electronic control units 10-1 to 10-4, creates an action plan for continuing safe traveling, and transmits control information to each of the onboard devices 20 via the electronic control units 10-1 to 10-4.

With a configuration in which all the onboard devices 20 and the integrated electronic control unit 60 are directly connected, the data input/output terminals of the integrated electronic control unit 60 and the wire harness for connection explosively increase. Thus, the electronic control units 10-1 to 10-4 are provided as relays for aggregating and spreading data.

In this manner, the onboard network is constructed by two networks of the backbone network that connects the integrated electronic control unit 60 and each of the electronic control units 10-1 to 10-4 and the local network that connects each of the electronic control units 10-1 to 10-4 and all the onboard devices 20.

The local network is separated at the onboard device 20 connected to a power train system, a chassis system, a steering system, a body system, and the like, and synthesized at the electronic control units 10-1 to 10-4. In the backbone network, all domains use a common network to communicate with the integrated electronic control unit 60. Thus, as for the data rate, the backbone network is equivalent to the local network, or the backbone network is faster than the local network.

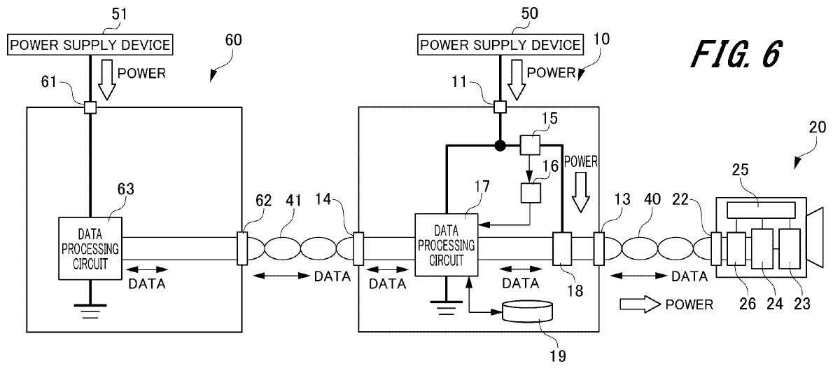

FIG. 6 is a configuration diagram conceptually illustrating a configuration example of an onboard control unit according to Example 3 of the present invention.

In FIG. 6, one of the four electronic control units 10-1 to 10-4 in FIG. 5 is illustrated as the electronic control unit 10 as a representative. As for the relationship between the electronic control unit 10 and the onboard device 20, as in the case of the onboard control unit according to Example 2, a system configuration is adopted in which a power supply superposition technology of superimposing a power supply (power) on data is applied, and power transmission and data communication are performed by the same cable (data wire 40).

In the onboard control unit according to Example 3, as in the case of the onboard control unit according to Example 2, the electronic control unit 10 monitors the state of the onboard device 20 based on the current value measured by the ammeter 15. Then, the data is transmitted from the electronic control unit 10 to the integrated electronic control unit 60 based on the information on the monitored state of the onboard device 20.

The integrated electronic control unit 60 includes at least a power supply terminal 61 and a data input/output terminal 62 as input/output interfaces with the outside, and power is supplied to the power supply terminal 61 from an external power supply device 51 such as a battery cell or a battery. A data wire 41 is connected between the data input/output terminal 62 of the integrated electronic control unit 60 and the data input/output terminal 14 of the electronic control unit 10. The integrated electronic control unit 60 includes at least a data processing circuit 63 therein. The data processing circuit 63 is supplied with power from the power supply device 51 via the power supply terminal 61.

The integrated electronic control unit 60 analyzes the information based on the sensor information of each of the onboard devices 20 supplied via the electronic control unit 10, determines vehicle control, and transmits a command of a control signal to each of the onboard devices 20. Thus, the integrated electronic control unit 60 requires a lot of signal processing and calculations. Since a very large amount of data is transmitted to the integrated electronic control unit 60, the data also temporarily includes sensor data that has not been acquired normally due to an environmental influence or the like. Since, of course, the result calculated with this data leads to an erroneous control result, the integrated electronic control unit 60 needs to determine the vehicle control while checking whether the directionality of the control result has not changed suddenly from the time-series control result. Thus, the integrated electronic control unit 60 needs to analyze the sensor data and also analyze the correctness while determining the vehicle control, and a lot of load is applied.

Currently, the electronic control unit 10 mainly performs a routing function. Providing the electronic control unit 10 with a function of determining the correctness of the data of the onboard device 20 and selecting the data to be transmitted makes it possible to reduce the load of the integrated electronic control unit 60. However, if the electronic control unit 10 checks the contents of the data one by one, the routing time greatly increases. The abnormality of the onboard device 20 appears in the consumption current of the onboard device 20 including the detection unit 23 and the communication unit 24. Each consumption current of the onboard device 20 has a specification. When the onboard device 20 operates normally, the consumption current of the onboard device 20 falls within the range of the specification.

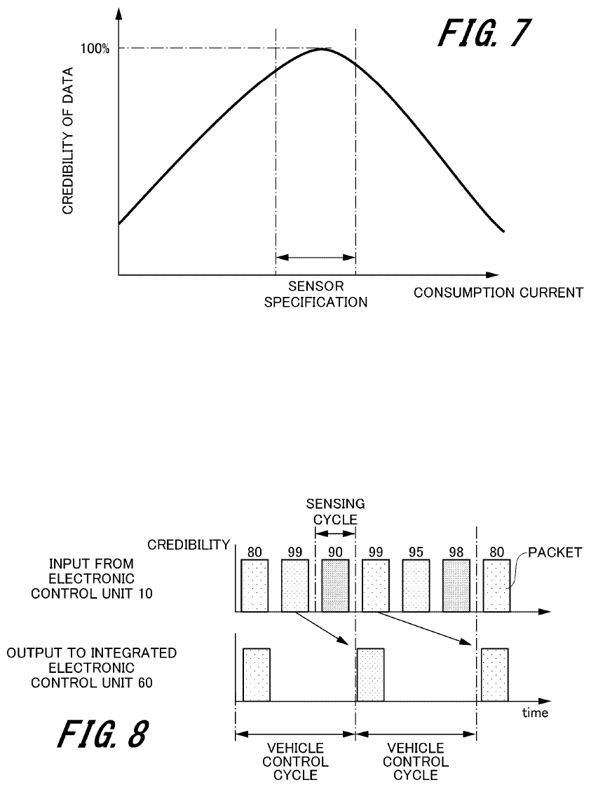

That is, as illustrated in FIG. 7, the state of the onboard device 20 can be predicted from the consumption current when the onboard device 20 acquires data. Then, the credibility of the data can be determined from the prediction result. By transmitting only the data with high credibility to the integrated electronic control unit 60, only the data with high credibility is transmitted to the integrated electronic control unit 60. As a result, the integrated electronic control unit 60 does not need to analyze the correctness and the like of the data, and thus, it is possible to reduce the load of the integrated electronic control unit 60.

FIG. 8 is a schematic diagram of data filtering through area electronic control for selecting data of the onboard device 20 in accordance with the vehicle control cycle.

Since the control cycle (vehicle control cycle) of the vehicle 70 is determined at regular intervals, the onboard device 20 performs sampling of data at a faster cycle than the control cycle of the vehicle 70, and transmits the sampled data to the electronic control unit 10. The electronic control unit 10 incorporates a memory 19, and stores the data sampled by the onboard device 20 in the memory 19 in association with the credibility of the data.

Then, the electronic control unit 10 uses the current value measured by the ammeter 15 as a parameter for determining the credibility of data, selects data having the highest credibility of data from among data sampled within the control cycle of the vehicle 70, and transmits the selected data to the integrated electronic control unit 60, thereby reducing the load on the integrated electronic control unit 60. Further, since the electronic control unit 10 can reduce the load of the backbone network, unnecessary speeding up of the backbone network can be suppressed. Thus, the cycle of data received by the electronic control unit 10 from the onboard device 20 is set to ½ or less as compared with the cycle in which the electronic control unit 10 transmits data to the integrated electronic control unit 60, and the electronic control unit 10 always selects data. This can transmit the data having the highest credibility in each control cycle to the integrated electronic control unit 60 as the data of the onboard device 20.

There is an optimum current value in the onboard device 20 such as a sensor, and the data of the onboard device 20 acquired in a state where the current is deviated from the optimum value is not normal data. Thus, in the onboard control unit according to Example 3, by associating the data acquired by the onboard device 20 with the current value at the timing when the onboard device 20 has acquired the data, the data in which the current value is abnormal is filtered, and is discarded without being transmitted to the backbone network. Since the electronic control unit 10 has this function, it is not necessary to transmit more data than necessary to the backbone network, which makes it possible to reduce the load of the backbone network. In addition, since unnecessary data processing in the integrated electronic control unit 60 as a higher-level device can be reduced, consumption current can also be reduced. That is, unnecessary acceleration of the backbone network is not needed, and a robust onboard network system can be constructed.

Meanwhile, with the change to a layered network with a zone architecture in which control processing is aggregated in the integrated electronic control unit (integrated ECU) 60, networks in various domains are integrated. Thus, the data of the onboard device having a high priority (hereinafter, it is abbreviated as high-priority data) directly linked to safe traveling, such as the brake or the steering and the data of the onboard device having a low priority whose slight delay is allowable (hereinafter, it is abbreviated as low-priority data), such as opening and closing of the window and audio control, are communicated by the same cable, which causes congestion to occur.

When transmission of low-priority data is started with congestion, it is necessary to wait until transmission of the low-priority data ends even though high-priority data is desired to be transmitted, which causes a delay in transfer time.

To reduce the latency time due to this congestion, it is necessary to speed up the network. In addition, introduction of a method of dividing a band and time of high-priority data by introducing a time sensitive network (TSN) standard has been studied. According to the present standard, the delay time of communication is secured, but low-priority data cannot be transmitted in the time secured for high-priority data even when there is no high-priority data. In addition, it is necessary to secure the time for high-priority data with a margin, and the network load cannot be increased, which requires a high-speed network.

### Example 4

Example 4 of the present invention is a modification of Example 2, and is a configuration example in which a thermometer 27 is provided in the onboard device 20, and a temperature at the time of acquiring the data of the onboard device 20 is measured and used as a parameter for determining credibility of data.

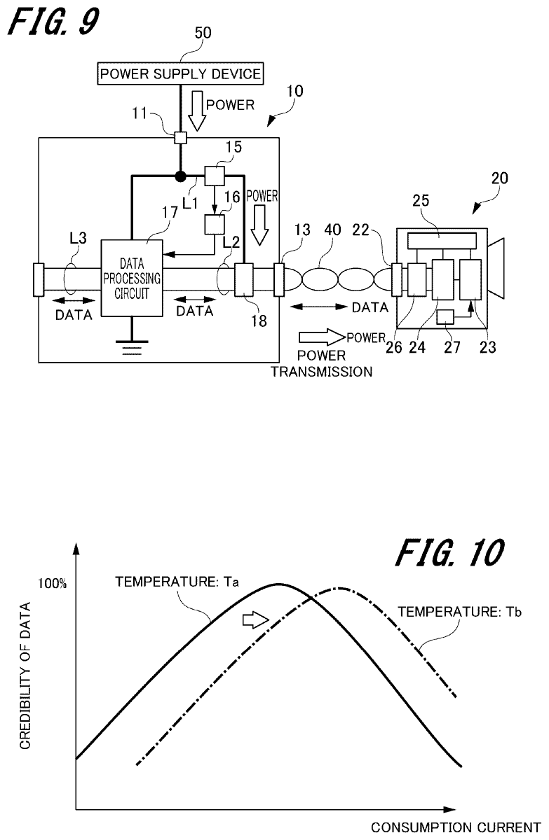

FIG. 9 is a configuration diagram conceptually illustrating a configuration example of an onboard control unit according to Example 4 of the present invention.

In the onboard device 20, the usage state of the consumption current changes depending on the ambient environment, in particular, the temperature. Thus, in the onboard control unit according to Example 4, the thermometer 27 is provided in the onboard device 20 to measure the temperature at the time of acquiring the data of the onboard device 20. The temperature information measured by the thermometer 27 is supplied to the detection unit 23 and transmitted to the electronic control unit 10 by the communication unit 24.

The electronic control unit 10 also uses temperature information transmitted from the onboard device 20 as a parameter for determining the credibility of data. That is, the electronic control unit 10 selects data to be transmitted to the integrated electronic control unit 60 based on the temperature information measured by the thermometer 27. Using temperature information at the time of acquiring the data of the onboard device 20 as a parameter for determining the credibility of data in this manner in addition to the data sampled by the onboard device 20 makes it possible to further reduce unnecessary data processing in the integrated electronic control unit 60. FIG. 10 illustrates a characteristic diagram of consumption current-credibility of data in a case where temperature information at the time of acquiring the data of the onboard device 20 is used as a determination parameter of the credibility of data.

In addition to the temperature information at the time of acquiring the data of the onboard device 20, the consumption current of the onboard device 20 also includes a secular change due to the use time of the product. Thus, by using the use time of the onboard device 20 as a parameter for determining the credibility of data in addition to the temperature information at the time of acquiring the data of the onboard device 20, it is possible to further improve the accuracy of the vehicle control.

### Example 5

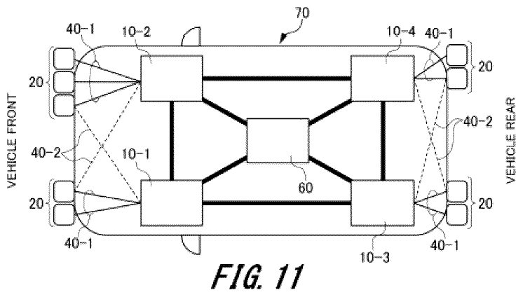

Example 5 of the present invention is a configuration example in which one onboard device 20 is connected to a plurality of electronic control units 10 to achieve redundancy. FIG. 11 is a connection diagram of an onboard network architecture according to Example 5 of the present invention.

In the onboard network system, a plurality of electronic control units 10 are disposed for respective locations of the vehicle 70, and a path for communicating from one electronic control unit 10 to the integrated electronic control unit 60 through a plurality of paths via the backbone network is provided in order to achieve redundancy. Similarly, in the onboard device 20 such as a sensor or an actuator, when one wire is sheared from the electronic control unit 10 in the connection using only the one wire, information of the onboard device 20 cannot be obtained.

Thus, in the onboard network architecture according to Example 5 of the present invention, one onboard device 20 is connected to a plurality of electronic control units 10 to achieve redundancy. Specifically, as illustrated in FIG. 11, each of a plurality of onboard devices 20 and one electronic control unit 10 (10-1 to 10-4) are connected by a data wire 40-1 corresponding to the data wire 40 in FIG. 5, and one onboard device 20 and one electronic control unit 10 are connected by another data wire 40-2.

With such a connection in which one onboard device 20 is connected to a plurality of electronic control units 10 by using the data wire 40-1 and the data wire 40-2 to achieve redundancy, when one of the data wire 40-1 and the data wire 40-2 is sheared, the information of the onboard device 20 can be obtained via the other wire.

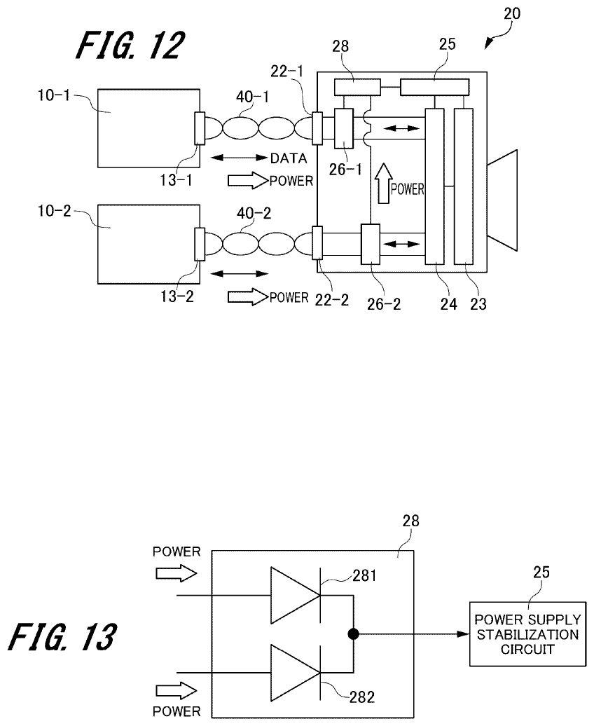

FIG. 12 is a configuration diagram conceptually illustrating a configuration example of an onboard control unit according to Example 5 of the present invention. Here, a configuration example in which one onboard device 20 is connected to a plurality of electronic control units, for example, two electronic control units 10-1 and 10-2 is illustrated. The onboard device 20 includes a power supply redundancy circuit 28, receives power from both of the two electronic control units 10-1 and 10-2 via the data wire 40-1 and the data wire 40-2, inputs the received power to the power supply redundancy circuit 28, and supplies optimum power from the power supply stabilization circuit 25 to the detection unit 23 and the communication unit 24.

FIG. 13 illustrates a configuration example of the power supply redundancy circuit 28. The power supply redundancy circuit 28 includes two diodes 281 and 282. According to the power supply redundancy circuit 28, even when the voltage of the power supplied by one data wire 40-1/40-2 of the data wire 40-1 and the data wire 40-2 has decreased, the onboard device 20 can be continuously driven by the power supplied by the other data wire 40-2/40-1.

### [Modification]

The present invention is not limited to the above-described examples, and it is needless to say that various other application examples and modifications can be taken without departing from the gist of the present invention described in the claims.

For example, in each of the examples described above, a sensor such as a CMOS sensor, a radar, an acceleration sensor, or a GPS sensor is exemplified as the onboard device 20, but the present invention is not limited to the sensor. The same operations and effects can be obtained in an actuator that performs a physical operation of the vehicle or a control board that controls the actuator.

In Example 3 to Example 5, a case where the present invention is applied to a zone architecture configuration has been described as an example, but the present invention is not limited to the application to the zone architecture configuration, and can also be applied to a domain architecture configuration. Thus, even when a zone architecture configuration and a domain architecture configuration are mixed in a vehicle or the like, the present invention can be applied to each of the zone architecture configuration and the domain architecture configuration.

### REFERENCE SIGNS LIST

10 (10-1 to 10-4) electronic control unit (zone ECU)
11, 12, 21 power supply terminal
13, 14, 22 data input/output terminal
15 ammeter
16 control unit
17 data processing circuit
18, 26 filter circuit
19 memory
20 onboard device
23 detection unit
24 communication unit
25 power supply stabilization circuit
27 thermometer
28 power supply redundancy circuit
30 power supply wire
40 (40-1, 40-2) data wire
50, 51 power supply device
60 integrated electronic control unit (integrated ECU)
181, 261 high-pass filter
182, 262 low-pass filter
281, 282 diode
L1 power-feeding path
L2, L3 line

1. An onboard control unit comprising:
an onboard device that controls traveling of a vehicle; and
an electronic control unit that collects information of the onboard device,
the onboard control unit feeding power supplied to the electronic control unit to the onboard device,
wherein the electronic control unit includes
a current measurement unit that measures a value of a current flowing through a power-feeding path that feeds power to the onboard device, and
a control unit that determines whether an abnormality has occurred in the onboard device based on the current value measured by the current measurement unit.

2. The onboard control unit according to claim 1, further comprising
a data wire through which data is exchanged between the electronic control unit and the onboard device, wherein
the electronic control unit includes a superimposition circuit that superimposes power supplied to the electronic control unit on data to be transmitted to the onboard device, and transmits the data on which the power is superimposed, the data being transmitted from the superimposition circuit, to the onboard device using the data wire.

3. The onboard control unit according to claim 2 further comprising,
an integrated electronic control unit as a higher-level device of the electronic control unit, wherein
when the control unit has detected that an abnormality has occurred in the onboard device, the electronic control unit transmits information indicating that the abnormality has occurred to the integrated electronic control unit.

4. The onboard control unit according to claim 3, wherein
the electronic control unit associates data acquired by the onboard device with the current value at a timing when the onboard device has acquired the data, and selects data to be transmitted to the integrated electronic control unit using the current value as a parameter for determining credibility of the data.

5. The onboard control unit according to claim 4, wherein
the onboard device includes a thermometer that measures a temperature at a time of data acquisition, and
the electronic control unit selects data to be transmitted to the integrated electronic control unit using temperature information measured by the thermometer as a parameter for determining credibility of the data.

6. The onboard control unit according to claim 3, wherein
a cycle of data received by the electronic control unit from the onboard device is ½ or less of a cycle of data transmitted from the electronic control unit to the integrated electronic control unit.
